(19) United States
(12) Patent Application Publication
(10) Pub. No.: US 2026/0068412 A1
(43) Pub. Date: Mar. 5, 2026

(54) THIN FILM PHOTOVOLTAIC DEVICE WITH LONG PRODUCT LIFE

(71) Applicant: Energy Materials Corporation, Rochester, NY (US)

(72) Inventors: Andenet Alemu, Perrysburg, OH (US); Thomas Nathaniel Tombs, Rochester, NY (US)

(21) Appl. No.: 19/104,511

(22) PCT Filed: Aug. 18, 2023
(86) PCT No.: PCT/US2023/030576

§ 371 Date: Feb. 18, 2025

Related U.S. Application Data
(60) Provisional application No. 63/399,442, filed on Aug. 19, 2022.

(51) Int. Cl. H10K 30/83; H10K 30/57; H10K 30/88; H10K 77/10; H10K 85/50; H10K 102/20

(52) U.S. Cl. CPC H10K 30/83; H10K 30/57; H10K 30/88; H10K 77/111; H10K 85/50; H10K 2102/20

(57) ABSTRACT

A thin film photovoltaic device is configured for receiving and converting a target wavelength range of light to electricity: The photovoltaic device includes a substrate, a bottom electrode disposed over the substrate, a lower carrier transport layer disposed over the bottom electrode, a perovskite absorber layer disposed over the lower carrier transport layer, an upper carrier transport layer disposed over the perovskite absorber layer, and a top electrode disposed over the upper carrier transport layer. The perovskite absorber layer has a physical thickness of 900 nm or less and is characterized by a bandgap energy (BE). At least one of the top and bottom 2024/039846 electrodes includes a transparent conducting layer which is transparent to the target wavelength range of light. The perovskite absorber layer has an optical path length that is greater than or equal to 8 times the physical thickness of the perovskite absorber layer for incident radiation that is i) within the target wavelength range, and ii) within an incident energy range of BE to (BE+0.52 eV).

### FIELD

The present disclosure relates to a Perovskite thin film photovoltaic device having a relatively thin Perovskite absorber layer and a relatively high optical path length for incident radiation.

### BACKGROUND

Since their first report in 2009, rapid improvements have enabled halide perovskite solar cells (PSCs) to become a promising technology for converting light to electricity as part of optoelectronic devices. To date, the power conversion efficiencies (PCEs) of solution-processed PSCs have been certified above 25 percent, competitive with the current dominant photovoltaic technology that is based on monocrystalline silicon (see National Renewable Energy Laboratories Efficiency Chart, https://www.nrel.gov/pv/cell-efficiency.html accessed Mar. 7, 2022 and page 23 of https://www.ise.fraunhofer.de/content/dam/ise/de/documents/publications/studies/Photovolta ics-Report.pdf). Whereas crystalline silicon is rigid, brittle, and requires costly, energy-intensive fabrication procedures, perovskites are flexible, easily processed at low temperatures, and up to a thousand times thinner. Furthermore, perovskites are solution-processable, which enables their manufacture with scalable, low-cost methods. These attributes open new opportunities to integrate solar power creatively and inexpensively into previously inaccessible markets, such as electric vehicles and buildings. PSCs advantages and high PCE put them on the path to be the next generation technology for utility, commercial, and residential photovoltaic applications.

In order for PSCs to gain market share in existing solar markets the speed of production must be fast enough so that capital equipment costs do not overly burden the ability to scale up for production and also so that the final cost of PSCs is competitive with the already mature manufacturing state of silicon-based solar cells.

Roll-to-roll (R2R) manufacturing is a very cost-effective option for devices including thin functional layers on low-cost substrates produced at high volumes. R2R manufacturing involves processing of a continuous sheet, or “web”, transferred between two moving rolls, on which additive and subtractive deposition processes are used to build structures in a sequential manner, layer by layer. Thin layers consume small quantities of specialty raw materials and can be deposited and dried quickly for high production speed. R2R processing is a scalable, low-cost method suitable for manufacturing of thin, Perovskite photovoltaic devices.

Scalable R2R deposition techniques include various coating, printing, and laminating mechanisms suitable for use at ambient environmental conditions of temperature, and pressure. Several scalable film deposition techniques have been developed for PSC fabrication, such as doctor-blading, spray deposition, slot-die coating, gravure coating, ink jet printing, dip coating, chemical bath deposition, flexographic, and electrodeposition. See Stranks, S. D. and Snaith, H. J., Metal-halide perovskites for photovoltaic and light-emitting devices, Nat. Nanotechnol. 10, 391-402 (2015); Deng, Y. et al., Scalable fabrication of efficient organolead trihalide perovskite solar cells with doctor-bladed active layers, Energy Environ. Sci. 8, 1544-1550 (2015); Yang, M. et al., perovskite ink with wide processing window for scalable high-efficiency solar cells, Nat. Energy 2, 17038 (2017); Barrows, A. T. et al., Efficient planar heterojunction mixed-halide perovskite solar cells deposited via spray-deposition, Energy Environ. Sci. 7, 2944-2950 (2014), Hwang, K. et al., Toward large scale roll-to-roll production of fully printed perovskite solar cells, Adv. Mater. 27, 1241-1247 (2015); He, M. et al. Meniscus-assisted solution printing of large-grained perovskite films for high-efficiency solar cells, Nat. Commun. 8, 16045 (2017); Chen, H., et al. A scalable electrodeposition route to the low-cost, versatile and controllable fabrication of perovskite solar cells, Nano Energy 15, 216-226 (2015); Kim, Y. Y. et al., Gravure-Printed Flexible perovskite Solar Cells: Toward Roll-to-Roll Manufacturing, Adv. Sci. 2019; and Deng, Y., et al., Vividly colorful hybrid perovskite solar cells by doctor-blade coating with perovskite photonic nanostructures, Mater. Horiz. 2, 578-583 (2015), each of which is incorporated by reference in its entirety. Scalable R2R drying includes in-line hot air drying and is often supplemented with in-line annealing. For a structure containing more than one functional layer, multiple stages of deposition and drying are connected in series.

Poor long term PCE stability of Perovskite photovoltaic devices is hindering efforts to broadly deploy perovskite photovoltaic technology in scalable, low-cost manufacturing. Poor long-term stability of PSCs is attributed to chemical degradation of the perovskite layer to a structure no longer useful for light conversion, e.g. chemical decomposition from MAPbI3 to PbI2 and from MAPbBr3 to PbBr2 (see Adv. Mater. 2020, 200110). The degradation process has also been demonstrated to be molecular desorption, initiating numerous research studies into techniques to recompense desorption loss or prevent desorption onset (see Joule 2021, https://doi.org/10.1016/j.joule.2021.03.015. A commercially viable means to reintroduce the evaporated species thus restoring the absorber layer as it degrades is yet to be realized (see J. Phys. Chem. Lett. 2018, 9, 11, 3000-3007). Encapsulation techniques to surround the PSC by a physical barrier have proven effective against chemical decomposition from oxygen or water exposure (see Coatings 9(2), 65). Two-dimensional (2D) perovskite structures created by halide and metal substitutions to the inorganic layer are proving more stable to extrinsic stresses but have lower PCE compared to conventional 3D lead halide perovskites (see APL Mater. 4, 091503 (2016), Advanced Materials, Volume 34, Issue 8, Feb. 24, 2022, 2105635, and Science 367, 1097-1104 (2020)). Derivative laboratory investigations of 2D structures for passivation continue. Interface passivation of the PSC layers promises improved stability against prolonged exposure to heat and light (e.g., see Advanced Energy Materials, Volume 9, Issue 12, Mar. 27, 2019, 1803450 and other references) but the additional processing involved to passivate layers increases manufacturing complexity and cost.

Most top performing PSCs with high PCE and long-term stability have been fabricated in research laboratories using the spin-coating method. Lab scale, spin-coated perovskite absorber layers have few intrinsic defects and can be coated thicker to compensate in part for the loss of PCE performance over time. However, neither the spin-coating method nor an increase of coating thickness to address stability are practical for use in scalable, low-cost methods. In a scalable, low-cost, manufacturing process like R2R, increasing the starting thickness of the perovskite layer to offset the impending loss, leads to lower peak PCEs due to charge-trapping defects in the perovskite thin film and poor dry film topography and crystal morphology degrades as the thickness of the wet film increases. Defects reduce current and power of a photovoltaic device, scale with thickness, and are difficult to prevent in low-cost, high speed manufacturing methods that utilize typical R2R deposition and drying techniques at ambient temperature, humidity, and pressure.

Commercially viable, thin Perovskite photovoltaic devices fabricated at low-cost in a high-speed manufacturing process with high and stable long-term PCE over expected product lifetime remain elusive.

### SUMMARY

A thin film photovoltaic device is configured for receiving and converting a target wavelength range of light to electricity: The photovoltaic device includes a substrate, a bottom electrode disposed over the substrate, a lower carrier transport layer disposed over the bottom electrode, a perovskite absorber layer disposed over the lower carrier transport layer, an upper carrier transport layer disposed over the perovskite absorber layer, and a top electrode disposed over the upper carrier transport layer. The perovskite absorber layer has a physical thickness of 900 nm or less and is characterized by a bandgap energy (BE). At least one of the top and bottom electrodes includes a transparent conducting layer which is transparent to the target wavelength range of light. The perovskite absorber layer has an optical path length that is greater than or equal to 8 times the physical thickness of the perovskite absorber layer for incident radiation that is i) within the target wavelength range, and ii) within an incident energy range of BE to (BE+0.52 eV). In some cases the incident energy range may correspond to a wavelength range of 600-800 nm.

Various embodiments in accordance with the disclosure have the advantages of stable, long-term photoconversion efficiencies. The PSC may be based on a hybrid organic-inorganic halide perovskite with appropriate carrier transport and transparent conducting layers for desired carrier selectivity, reduced series resistance losses and high-shunt resistances to avoid current leakage. The optical properties of the PSC functional layers are tuned to provide a long optical path for the impinging light. The long optical path maintains high light absorption despite perovskite layer degradation and loss of light absorbing material. The materials of the functional layers are suitable for use in low-cost, high-speed manufacturing of PSCs as disclosed in U.S. Pat. Nos. 11,108,007, 11,342,130, and US Patent Application Publication US2020377532, the disclosures of which are hereby incorporated in their entirety by reference.

### BRIEF DESCRIPTION OF THE DRAWINGS

Various embodiments of the invention are disclosed in the following detailed description and accompanying drawings.

FIG. 1 is a cross section of a portion of a multi-layer perovskite photovoltaic device according to some embodiments.

FIG. 2 is a schematic side view of an exemplary printing system for roll-to-roll printing on a flexible multilayer substrate.

FIG. 3 is a schematic side view of an exemplary multi-station deposition and drying device for roll-to-roll printing a photovoltaic device on a flexible multilayer substrate.

FIG. 4 is measured Optical Thickness of degrading perovskite samples.

FIG. 5 is measured Jsc of a PAL during an accelerated life test at 85° C. and projected Jsc for a model PAL.

FIG. 6 is measured OT and projected OT for a model PAL.

FIG. 7 is projected PCE for three model PALs.

FIG. 8 is predicted photoconversion efficiency as a function of degrading OT for 5 modeled PALs.

FIG. 9A is an illustration of the structural layout for a mono-facial single junction perovskite solar cell according to some embodiments.

FIG. 9B is an illustration of the structural layout for another mono-facial single junction perovskite solar cell according to some embodiments.

FIG. 10 is an illustration of the structural layout for a bi-facial single junction perovskite solar cell according to some embodiments.

FIG. 11 is a cross sectional view of another non-limiting example of a bifacial perovskite photovoltaic device according to some embodiments.

FIG. 12 is a non-limiting example of a tandem perovskite photovoltaic device according to some embodiments.

FIG. 13 is a cross sectional view of another non-limiting example of a perovskite photovoltaic device according to some embodiments.

It is to be understood that the attached drawings are for purposes of illustrating the concepts of the disclosure and may not be to scale. Identical reference numerals have been used, where possible, to designate identical features that are common to the figures.

### DETAILED DESCRIPTION

The present disclosure is inclusive of combinations of the embodiments described herein. References to “a particular embodiment” and the like refer to features that are present in at least one embodiment of the disclosure. Separate references to “an embodiment” or “particular embodiments” or the like do not necessarily refer to the same embodiment or embodiments; however, such embodiments are not mutually exclusive, unless so indicated or as are readily apparent to one skilled in the art. It should be noted that, unless otherwise explicitly noted or required by context, the word “or” is used in this disclosure in a non-exclusive sense.

The example embodiments of the present disclosure are illustrated schematically and not necessarily to scale for the sake of clarity. One of ordinary skill in the art will be able to readily determine the specific size and interconnections of the elements of the example embodiments of the present disclosure. It is to be understood that elements not specifically shown, labeled, or described can take various forms well known to those skilled in the art. It is to be understood that elements and components can be referred to in singular or plural form, as appropriate, without limiting the scope of the disclosure.

A perovskite photovoltaic (PV) structure is intended to receive light (typically visible, IR, or UV light) and convert it into electricity. As such, various layers and features may need to be reasonably transparent to this light to ensure that an appropriate amount reaches the perovskite absorber layer(s). Herein, unless otherwise noted, the terms “transparent”, “transparency”, “transmissivity” or the like, are generally relative to the target wavelength or wavelength range for conversion to electricity. This target wavelength or wavelength range may be different for different systems. In some embodiments, the target wavelength range may correspond to the solar radiation spectrum or a portion thereof. In some cases, the target wavelength range may correspond to the visible light spectrum or a portion thereof. In some cases, the target wavelength range may correspond to the infrared or UV spectrum, or a portion thereof. In some embodiments, the target wavelength range may be defined as a particular wavelength, e.g., 400 nm, 450 nm, 500 nm, 550 nm, 600 nm, 650 nm, 700 nm, or 750 nm, or any other wavelength of interest in the IR, visible, or UV portions of the spectrum intended for energy conversion. In some cases, a target wavelength range may be defined as an explicit range, e.g., 400-425 nm, 425-450 nm, 450-475 nm, 475-500 nm, 500-525 nm, 525-575 nm, 575-600 nm, 600-625 nm, 625-650 nm, 650-675 nm, 675-700 nm, 700-725 nm, 725-750 nm, or any combination of ranges thereof, or any other wavelength range of interest.

In some embodiments, something (e.g., a layer, a component, a structure, or the like) that is “transparent” transmits at least 50% of incident radiation within the target wavelength range, i.e., a transmittance (%T) of 50%. Something that is considered light transmissive generally transmits at least 10% of incident radiation within the target wavelength range. Transmittivities in the range of 10% up to 50% may be considered partially transparent. A light-transmissive component, layer, or structure may be either transparent or partially transparent.

Besides the light-absorbing properties of a layer, a component, a structure, or the like, its apparent transparency may in some cases be affected by refractive index mismatches, surface structures, or other factors that may result in reflective losses and/or light scattering. Another way to describe transparency is in terms of absorptance (%A). In some embodiments, something that is “transparent” may have an absorptance of 50% or less with respect to incident radiation within the target wavelength range. Something that is considered light transmissive may have an absorptance of 90% or less of incident radiation within the target wavelength range. Absorptances in a range of 50% up to 90% may be considered partially transparent.

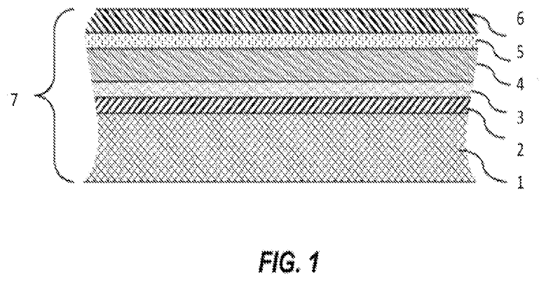

Shown in FIG. 1 is a cross section of a portion of a multi-layer perovskite photovoltaic device 7. The structure of photovoltaic device 7 may include a relatively thick (e.g., 5 to 200 microns) support 1 (optionally flexible) with several, generally thinner, functional layers provided over the support. Over support 1 are provided a bottom electrode 2, a lower carrier transport layer 3, a perovskite absorber layer (“PAL”) 4, an upper carrier transport layer 5, and a top electrode 6. At least one of the top and bottom electrodes includes a transparent conducting layer that is transparent to a target wavelength range of light. In some embodiments, the photovoltaic device may have a bifacial structure that is able to receive light through both electrodes. For example, a bifacial structure may be one where both of the top and bottom electrodes are transparent, or alternatively, where one electrode is transparent and the other electrode is partially transparent. In some embodiments, a transparent electrode may include a conductive metal oxide such as indium doped tin oxide (ITO), aluminum doped zinc oxide (AZO), or fluorine doped tin oxide (FTO). In some cases, the transparent electrode may further include a pattern of metal lines that may reduce overall resistance without obstructing much light. The carrier transport layers are generally transparent to the target wavelength.

In operation, positive and negative charges (holes and electrons) are produced in the perovskite absorber layer 4 in response to absorption of target radiation. The lower and upper carrier transport layers (3, 5) receive these separated charges and transfer them to the respective bottom and top electrodes (2, 6). The bottom and top electrodes may be in electrical contact with an electrical device (not shown in FIG. 1) where the collected charges serve to power the device, or alternatively charge it in the case where the electrical device is an energy storage battery of some sort.

In some embodiments, the lower carrier transport layer may include a hole transporting material (i.e., the lower carrier transport layer is a hole transporting layer) and the bottom electrode may act as an anode in the photovoltaic structure. In such embodiments, the upper carrier transport layer may include an electron transporting material (i.e., the upper carrier transport layer is an electron transporting layer) and the top electrode may act as a cathode in the photovoltaic structure. Such an arrangement of layers where the anode is a bottom electrode proximate the substrate and the cathode is a top electrode distal the substrate may for convenience be referred to as a PIN structure.

In some preferred embodiments, the lower carrier transport layer may include an electron transporting material and the bottom electrode may act as a cathode in the photovoltaic structure. In such embodiments, the upper carrier transport layer may include a hole transporting material and the top electrode may act as an anode in the photovoltaic structure. Such an arrangement of layers where the cathode is a bottom electrode proximate the substrate and the anode is a top electrode distal the substrate may for convenience be referred to as a NIP structure.

The thickness of a carrier transport layer depends in part on the properties of the overall photovoltaic stack, but in some embodiments, may have an average thickness in a range of ten to hundreds of nanometers.

The term “perovskite layer” is a continuous layer of organic-inorganic hybrid perovskite material with an ABX3 crystal lattice where A and B are two cations of very different sizes, and X is an anion that coordinates to both cations. Perovskite precursor material is defined as an ionic species where at least one of its constituents becomes incorporated into the final perovskite layer ABX3 crystal lattice. Organic perovskite precursor material are materials whose cation contains carbon atoms while inorganic perovskite precursor material are materials whose cation contains metal but does not contain carbon. Examples of inorganic perovskite precursors for making perovskite solutions include lead (II) iodide, lead (II) acetate, lead (II) acetate trihydrate, lead (II) chloride, lead (II) bromide, lead nitrate, lead thiocyanate, tin (II) iodide, rubidium halide, potassium halide, and cesium halide. Examples of organic perovskite precursors for making perovskite solutions include methylammonium iodide, methylammonium bromide, methylammonium chloride, methylammonium acetate, formamidinium bromide, and formamidinium iodide. To produce a high performing perovskite device, it is preferred that the organic perovskite precursor material has a purity greater than 99 percent by weight and the inorganic perovskite precursor has a purity greater than 99.9 percent by weight. The inorganic perovskite precursor contains a metal cation and the preferred metal cation is lead. In the preferred embodiment the molar ratio of organic perovskite precursor material to inorganic perovskite precursor material is between one and three.

In some embodiments, the perovskite solution includes an organic perovskite precursor material, an inorganic perovskite precursor material, and solvent wherein the amount of solvent is greater than 30 percent by weight and the perovskite solution has a total solids concentration by weight that is between 30 percent and 70 percent of the perovskite solution's saturation concentration at the provided solution temperature (i.e., temperature the solution is maintained at prior to deposition of the solution onto the flexible substrate). In preferred embodiments, the solvent may include one or more alcohols and the preferred provided solution temperature is between 20 and 50° C. In further preferred embodiments, it is preferred to have an amount of alcohol that is less than 50 percent by weight and a total solids concentration greater than 35 percent by weight. In another preferred embodiment the perovskite solution has an amount alcohol that is greater than 50 percent by weight and a total solids concentration less than 40 percent by weight. In another preferred embodiment, the perovskite solution has a total solids concentration between 30 and 45 percent by weight and an amount of 2-methoxyethanol that is greater than 55 percent by weight.

Some non-limiting examples of materials that may be useful as support 1 include polyethylene terephthalate (PET), thin flexible glass such as Corning® Willow® Glass, polyethylene naphthalate (PEN), polycarbonate (PC), polysulfone, metal foil (e.g., copper, nickel, titanium, steel, aluminum, or tin), and polyimide. With the exception of using metal foil, the preferred thickness of support 1 is generally in range from 25 to 200 microns. When metal foil is used the preferred thickness of the metal foil is generally between 5 and 50 microns. The substrate or an interface between the substrate and the bottom electrode may in some cases include reflective or opaque light scattering layer, e.g., a polymer layer including titanium dioxide particles. The substrate may include a textured or nanostructured layer or surface.

Some non-limiting examples of materials that may be useful for the bottom electrode 2, particularly when used as the window for the photovoltaic device may include transparent and partially transparent electrodes based on or that include: metal-nanowires and metal thin-films (see J. Mater. Chem. A, 2016, 4, 14481-14508, which is incorporated by reference in its entirety); metal mesh and metal grid electrodes made with metal nanoparticles, particulate metal paste, and/or electroplating; poly(3,4-ethylenedioxythiophene) (PEDOT) complex such as poly(3,4-ethylenedioxythiophene): polystyrene sulfonate (PEDOT:PSS); doped and undoped metal oxides such as tin oxide (doped with indium or fluorine), molybdenum oxide, and zinc oxide (doped with aluminum). A metal foil may be used as the bottom electrode 2 when not on the window side or otherwise not intended to transmit light. In some cases, the metal foil may form both the support 1 and the bottom electrode in combination. The metal foil can be made from a wide range of metals but preferably includes copper, nickel, aluminum, silver, or stainless steel. The metal foil may have more than one layer of metal such as copper coated with nickel or tin. The metal foil may also be part of a laminate structure and include plastic layers such as PET or polyimide and optionally an adhesive interlayer. Such structures may be referred to as metallized plastics. The term “metal foil” as used herein generally includes metallized plastics unless otherwise noted or context dictates otherwise. The bottom electrode may in some cases be reflective and/or light scattering. The bottom electrode may in some embodiments include a textured or nanostructured layer or surface.

The top electrode 6 may be formed from a similar set of materials as described for the bottom electrode 2. For example, when the top electrode is intended to receive radiation in a target wavelength, it may include a transparent metal oxide (ITO, AZO, FTO), nanowires, a patterned metal mesh or the like. When the top electrode is not intended to receive target radiation, it may optionally be made of a generally opaque metal layer (e.g., copper or silver) that may also be reflective and/or light scattering. In some cases, the top electrode includes a textured or nanostructured layer or surface. Some non-limiting examples of hole-transporting materials may include a poly(triaryl amine) (e.g., poly[bis(4-phenyl)(2,4,6-trimethylphenyl)amine]), a poly-(N-vinyl carbazole), PEDOT complex, a poly(3-hexylthiophene), spiro-MeOTAD (also known as N²,N²,N²′,N²′, N⁷,N⁷,N⁷,NT-octakis(4-methoxyphenyl)-9,9′-spirobi[9H-fluorene]-2,2′,7,7′-tetramine), poly-TPD, EH44, certain metal oxides (e.g. nickel oxide, molybdenum oxide, and vanadium oxide, any of which may optionally be doped), and certain self-assembled monolayers (e.g. 2-(9H-Carbazol-9-yl)ethyl]phosphonic acid)

Some non-limiting examples of electron-transporting materials may include fullerenes, (e.g., phenyl-C61-butyric acid methyl ester (PCBM) and fullerene-C60), bathocuproine (BCP), TPBI, PFN, PC₇₁BM, ICBA, graphene, reduced graphene oxide, certain metal oxides (e.g., tin oxide, zinc oxide, cerium oxide, and TiO₂, any of which may optionally be doped).

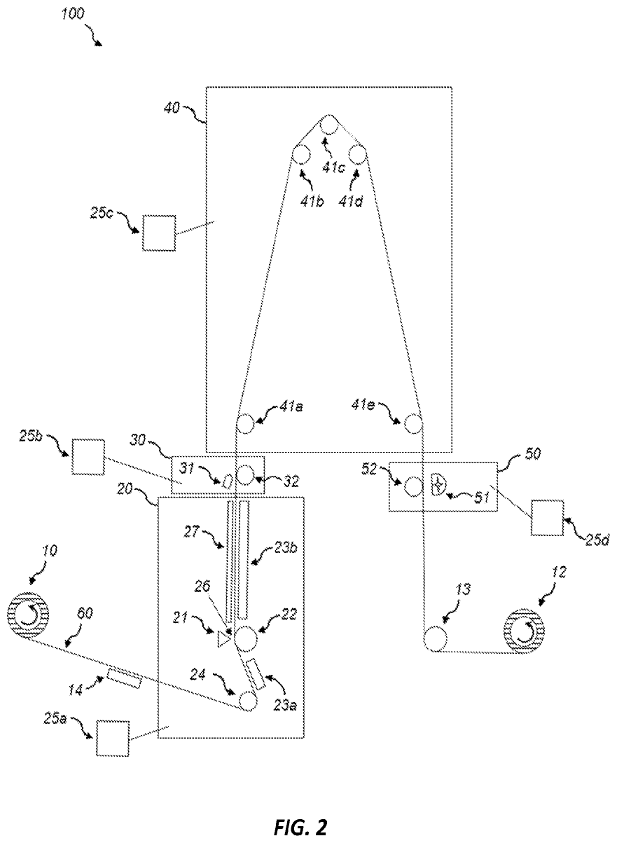

Many types of deposition and drying devices are known to those skilled in the art and a variety of devices are envisioned to be configured to use the methods described in the embodiments of the disclosure. A high speed, roll-to-roll (R2R) deposition and drying device that conveys a flexible substrate from a roll through the device will enable production of a perovskite layer at low cost. FIG. 2 shows a schematic of an exemplary R2R deposition and drying device 100 that will be used to describe preferred embodiments of the disclosure. Additional configurations can be adapted to enable the multistep process of the disclosure by those skilled in the art. A flexible multilayer substrate 60 is unwound from a unwind roll 10 and threaded through a deposition (and first drying step) section 20, a fast drying (second drying step) section 30, a long duration heating section 40, and a short duration heating section 50, then wound onto a rewind roll 12. Other components in R2R deposition and drying devices known in the industry are considered useful for this disclosure but are not shown in FIG. 2. For example, a cooling section (not shown) may be useful prior to the rewind roll 12. The direction of movement of the flexible multilayer substrate 60 through the R2R deposition and drying device 100 is identified by the arrows in the unwind roll 10 and the rewind roll 12. A surface treatment device 14 conditions the surface of the flexible multilayer substrate 60 prior to deposition of the perovskite solution. Surface treatment devices include corona discharge, ozone (created, for example, with ultraviolet radiation), and plasma. Surface treatment devices can operate in ambient air, conditioned air (where temperature and relative humidity are controlled), oxygen, or inert gas such as nitrogen or argon.

The deposition (and first drying step) section 20 of the R2R deposition and drying device 100 includes one or more conveyance rollers 24 to direct the path of the flexible multilayer substrate 60 so that it is correctly presented to the deposition device 21 as well as correctly conveyed through the deposition section 20. Conveyance rollers, tensioning rollers, and web guidance rollers are typically used throughout deposition and drying devices to aid in conveying flexible substrates, controlling tension and position. A conveyance roller 13 is shown prior to the rewind roll 12 and conveyance rollers 41a-e are shown in the long duration heating section 40. To simplify FIG. 2 additional rollers are not shown. Conveyance rollers may include air bearings to minimize or eliminate contact with the flexible multilayer substrate 60. Air flotation methods (not shown) known by those skilled in the art may also be used to minimize or eliminate contact between conveyance rollers and the flexible multilayer substrate 60.

The deposition device 21 that deposits a layer of perovskite solution including a solvent and perovskite precursor material to the flexible multilayer substrate 60 can be any number of known deposition devices but is preferred to be based on a slot die or gravure system (direct, reverse, or offset) deposition device. Other deposition devices envisioned for use in the disclosure include spray, dip coat, inkjet, flexographic, rod, and blade. The perovskite solution is supplied to the deposition device 21 by methods and devices known by those skilled in the art (not shown). The deposited perovskite solution layer is partially dried in section 20 in a first drying step by removing a first portion of solvent from the deposited solution while heating the deposited solution to a coated layer temperature. To optimize the drying conditions and to improve the wettability of the layer of perovskite solution deposited on to the flexible multilayer substrate 60 the temperature of the perovskite solution and the coating device is preferably controlled by a temperature controller (not shown). The setpoint for the temperature of the perovskite solution deposited on the multilayer substrate 60 depends on the formulation of the perovskite solution. The preferred temperature range for the heated deposited perovskite solution in the first drying step is between 30 and 100° C. and a more preferred temperature range is between 35 and 60° C. The thickness of the perovskite solution initially deposited on the flexible multilayer substrate 60 is preferably less than 10 microns to minimize nonuniformities created by convective flow in the coated layer and greater than 2 microns to enable sufficient wetting of the perovskite solution with the flexible multilayer substrate 60. A backing roller 22 or set of rollers is used to set the engagement, gap or load to the deposition device 21.

To optimize drying conditions in the first drying step, the amount of air flow around the wet coating on the multilayer substrate 60 can optionally be controlled by constraining the movement of air above the wet coating with an air flow control device 27 such as screens, baffles or plenums. The temperature and humidity of deposition section 20 may be controlled by an environmental controller 25a to optimize the coating and drying conditions in deposition section 20. Optional control of the temperature of backing roller 22 is envisioned as well as control of the temperature of the flexible multilayer substrate prior to and subsequent to the deposition device 21 as depicted by plenums 23a and 23b, however, heated rollers, or heated fixed curved surfaces are also envisioned to control the temperature of the flexible multilayer substrate with conductive heating. Backing roller 22 can act as a substrate heating device that heats the flexible multilayer substrate. The backing roller 22 can have fluid flowing through it to maintain a preset temperature. This type of roller is sometimes called a jacketed roller. The preferred range that a substrate heating device heats the flexible multilayer substrate to prior to depositing the layer of perovskite solution is between 30 and 100° C.

The flexible multilayer substrate 60 enters a fast-drying section 30 with the wet coating of the perovskite solution on the flexible multilayer substrate 60 that was applied by deposition device 21. The first drying step is defined by the removal of a first portion of perovskite solution in the region between the deposition device 21 and the fast-drying section 30. The amount of solvent removed in the first drying step is an important factor in making a uniform coating. This first drying step is affected by: the length of the first drying region, which is the distance between the deposition location 26 and the entrance of the fast-drying section 30; the temperature of deposition section 20, the temperature, speed, surface energy, and surface area of the flexible multilayer substrate 60; the amount of air flow around the wet coating of the perovskite solution on the flexible multilayer substrate 60 in the first drying region; and the formulation of the perovskite solution. The preferred temperature of the area around the flexible multilayer substrate 60 and the perovskite solution is between 30 and 100° C. during the first drying step.

The fast-drying section 30 defines a second drying step where a second portion of the solvent from the perovskite solution is removed, where the second drying step has a higher rate of solvent evaporation than the first drying step. Any suitable device that causes rapid solvent removal from the wet coating can be used and may include a non-contact drying device 31 or a contact drying device 32 where contact is defined by physically contacting the flexible multilayer substrate. Non-contact drying devices include air knives, infrared heaters, microwave heaters, convection ovens, Rapid Thermal Processors, and high energy photonic devices such as Xenon lamps. Contact drying devices include conduction heaters such as heated rollers or station curved plates that contact the side of the web opposite the wet coating. A non-contact drying device 31 used in the preferred embodiment of the disclosure is an air knife that blows gas, such as air or nitrogen, across the surface of the coating to lower the solvent vapor pressure and quickly remove the evaporating solvent. The temperature of the gas is optionally controlled (not shown). Some non-contact drying devices may benefit by the use of a nearby backing roller or rollers to control the spacing to the non-contact device 31 or to aid in drying the perovskite solution. The temperature and humidity of the fast-drying section 30 may also be controlled by an environmental controller 25b to optimize the conditions of the second drying step.

The second drying step causes a conversion reaction in the perovskite solution that is induced by the rapid evaporation of the solvent from the solution causing saturation of the solids and crystal formation or formation of an intermediate phase. The conversion reaction is typically readily visually apparent as it changes the color or optical density of the perovskite solution. The degree of color change and change in optical density of the perovskite solution depends on the type and quantity of perovskite precursors that are present in the deposited perovskite solution. In order to create a uniform perovskite layer the conversion reaction must be fast in the second drying step so that the movement of the crystals is minimized as they are formed. The conversion reaction that occurs in the second drying step causes the perovskite solution to have a large reduction in the transmission of visible light. Preferably, the percent transmission of visible light through the perovskite solution due to the conversion reaction in the second drying step is reduced by at least a factor of 2. The percent transmission of visible light is defined by the amount of visible light leaving the sample divided by the amount of visible light entering the sample and can be measured by known methods such as directing white light on the deposited perovskite solution both prior to entering and after exiting the second drying location. The percent transmission of visible light is determined by measuring the visible light intensity both entering and exiting the flexible multilayer substrate at the two locations. If the flexible multilayer substrate is opaque then a reflection measurement can be used to determine percent transmission of visible light through the perovskite solution.

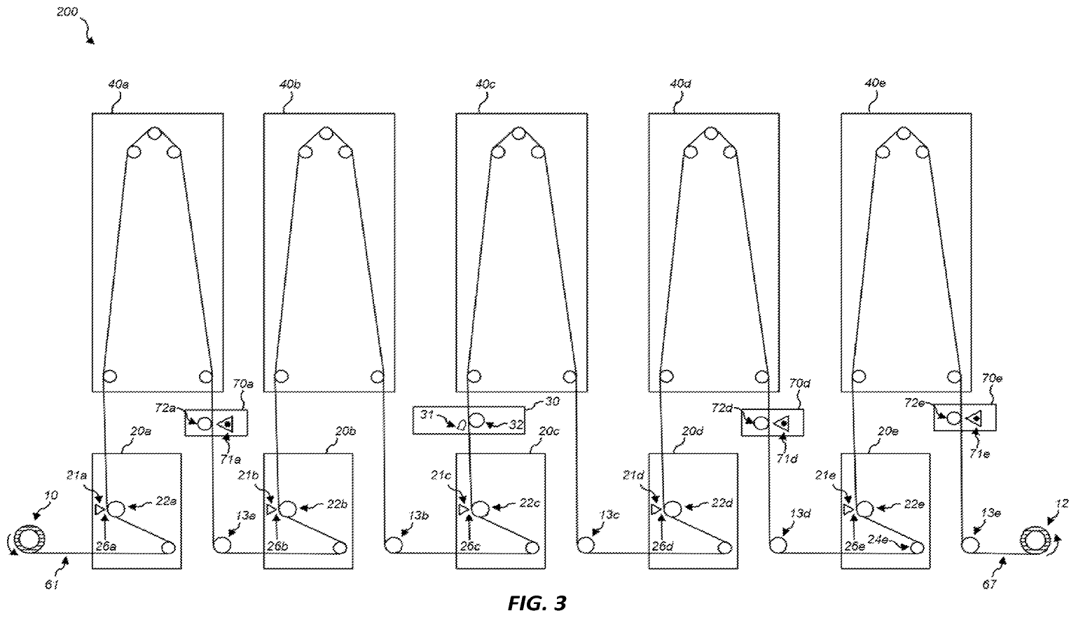

FIG. 3 shows a schematic of an exemplary multi-station R2R deposition and drying device 200 for roll-to-roll printing a photovoltaic device on a flexible substrate that will be used to describe preferred embodiments of the disclosure. A station of the multi-station R2R deposition and drying device 200 is defined as including a deposition section but other sections and devices may be part of the station. Additional configurations can be adapted to enable the multistep process of the disclosure by those skilled in the art to make some or all layers of perovskite devices, especially perovskite solar cells. While FIG. 3 shows five stations, more or less than five stations are envisioned for variations on preferred embodiments of the disclosure. For example, a multi-station R2R deposition and drying device with three stations (not shown) could be used to apply a first (lower) carrier transport layer, a perovskite absorber layer, and a second (upper) carrier transport layer in succession on top of a flexible substrate having a first electrode layer and a support layer. Another example is a multi-station R2R deposition and drying device with four stations (not shown) where the first (bottom) electrode layer is formed on the flexible substrate in the first station of the multi-station R2R deposition and drying device prior to the deposition of the first carrier transport layer. In this example, the device is supplied with a flexible substrate having only a support layer. Alternatively, when the multi-station R2R deposition and drying device is provided with a flexible substrate having a support and a first electrode layer, the fourth station could be used to apply a second (top) electrode layer on to the second carrier layer. A multi-station R2R deposition and drying device with more than five stations is envisioned to make photovoltaic devices that require additional layers that improve the performance or functionality of the photovoltaic devices.

In FIG. 3 a flexible support 61 is unwound from an unwind roll 10 and threaded through five deposition sections 20a-e and five long duration heating sections 40a-e, in a continuous inline process to make a perovskite photovoltaic device 67. The direction of movement of the flexible substrate 61 through the multi-station R2R deposition and drying device 200 is identified by the arrows adjacent to the unwind roll 10 and the rewind roll 12. Additional devices after each deposition section or long duration heating section are envisioned and some are shown in FIG. 3 and described below. Each deposition section 20a-e deposits a functional solution on to the flexible support 61 at the associated deposition location 26a-e with a deposition device 21a-e. Each long duration heating section 40a-e heats the functional solution deposited by the associated deposition device to dry, cure, anneal, and/or sinter the functional solution. Typically, process setpoints for each long duration heating section 40a-e are different as they are optimized for the solution that is deposited by the associated deposition device. Likewise, the process configurations and setpoints for each deposition section 20a-e may also be different from each other.

A preferred embodiment of a multi-station R2R deposition and drying device 200 is described here in more detail. Deposition section 20a deposits a first electrode solution on the flexible support 61 with a first electrode deposition device 21a. Long duration heating section 40a dries and sinters the first electrode solution to form a first electrode layer. The flexible substrate with the first electrode layer then travels to the deposition section 20b where a first carrier transport solution is deposited on the first electrode layer with a first carrier transport deposition device 21b. Long duration heating section 40b dries and sinters the first carrier transport solution to form a first carrier transport layer. The flexible substrate with the first electrode layer and the first carrier transport layer then travels to the deposition section 20c where a perovskite solution is deposited on the first carrier transport layer with a perovskite solution deposition device 21c. A first portion of the initial amount of solvent in the deposited perovskite solution is removed in section 20c in a first drying step, similarly as described for section 20 in FIG. 2. After deposition section 20c, the flexible substrate travels through a second drying step fast drying section 30, where a second portion of the initial amount of solvent in the deposited perovskite solution is removed. Note that the description of the fast drying section appears above in the description of FIG. 2, wherein the second drying step causes a conversion reaction in the perovskite solution that is induced by the rapid evaporation of the solvent from the solution causing saturation of the solids and crystal formation or formation of an intermediate phase. After fast drying section 30, long duration heating section 40c further dries and anneals the coated perovskite solution to form a perovskite layer. The flexible substrate with the first electrode layer, the first carrier transport layer, and the perovskite layer then travels to the deposition section 20d where a second carrier transport solution is deposited on the perovskite layer with a second carrier transport deposition device 21d. Long duration heating section 40d dries the second carrier transport solution to form a second carrier transport layer. The flexible substrate with the first electrode layer, the first carrier transport layer, the perovskite layer, and the second carrier transport layer then travels to the deposition section 20e where a second electrode solution is deposited on the second carrier transport layer with a second electrode deposition device 21e. Long duration heating section 40e dries the second electrode solution to form a second electrode layer. The flexible substrate with the five functional layers is then wound onto a rewind roll 12.

Laser etching of thin films is known in the art and may be used here to create a monolithic photovoltaic device as part of the inline continuous manufacturing process. Between the long duration heating section 40a and deposition section 20b, the flexible substrate travels through a laser etch unit 70a. Between the long duration heating section 40d and deposition section 20e, the flexible substrate travels through a laser etch unit 70d. Between the long duration heating section 40e and rewind roll 12, the flexible substrate travels through a laser etch unit 70e. Each laser etch unit contains a laser device 71a, d, e, and a laser etch backing roller 72a, d, e. The laser etch backing rollers 72a, d, e are used to ensure that the flexible support 61 is in a known location. A vision system (not shown) can be incorporated in one or more of the laser etch units 70a, d, e to increase the accuracy of the location that the laser etches. A control system (not shown) can be incorporated in one or more of the laser etch units 70a, d, e to position the laser spots based on data collected. Feed forward and feedback may be used in the control system. Laser etch unit 70a removes a portion of the first electrode layer. Laser etch unit 70d removes a portion of the second carrier transport layer, a portion of the perovskite layer, and a portion of the first carrier transport layer. Laser etch unit 70e removes a portion of the second electrode layer, a portion of the second carrier transport layer, a portion of the perovskite layer, and a portion of the first carrier transport layer.

All of the further sections and elements shown in FIG. 2 and described above are envisioned to be included in the preferred multi-station R2R deposition and drying device to make the perovskite layer but are not shown in FIG. 3 for clarity. Some of the sections and elements shown in FIG. 2 are also envisioned for use in making the other layers in the multi-station R2R deposition and drying device but are not shown in FIG. 3 for clarity. For example, a surface treatment device 14 may be used to condition the flexible support 61 or one or more of the layers made on the flexible support 61 prior to entering each deposition section 20a-e, and environmental controllers may be used for some or all of the deposition sections 20a-e and long duration heating sections 40a-e. The use of conveyance rollers and backing rollers for R2R machines have been described above and only a small number of conveyance rollers 13a-e and backing rollers 22a-e are identified in FIG. 3. Other conventional components in R2R deposition and drying devices are known in the industry are envisioned for use in the method of this disclosure but are not shown in FIG. 3.

The main parameters characterizing the performance of a solar cell are peak power (Pmax), open circuit voltage (Voc), short circuit current (Isc), and fill factor (FF). The power conversion efficiency (PCE) is the fraction of incident solar power converted to electrical power and can be determined from Pmax, Voc, Isc, and FF. Isc is the maximum photogenerated current delivered by a solar cell. Short circuit current density (Jsc) is the Isc divided by solar cell area. The Voc is the maximum voltage delivered by a solar cell. By increasing the resistive load from zero (short circuit) to a very high value (open circuit), the load that delivers maximum power (Pmax) at fixed level of irradiation can be determined. The fill factor FF is the ratio of Pmax to the product of Isc and Voc. Theoretical values of these performance metrics are generally determined using a detailed balance model. The ideal Voc is limited by the band gap energy of the absorbing material. Band gap energy is the minimum energy required to move an electron from the valence band to the conduction band of a light absorbing material. Standard test conditions (STC) are used to compare performance of solar cells: irradiance of 1000W/m2, AM (air mass) 1.5 spectrum, and cell temperature of 25° C.

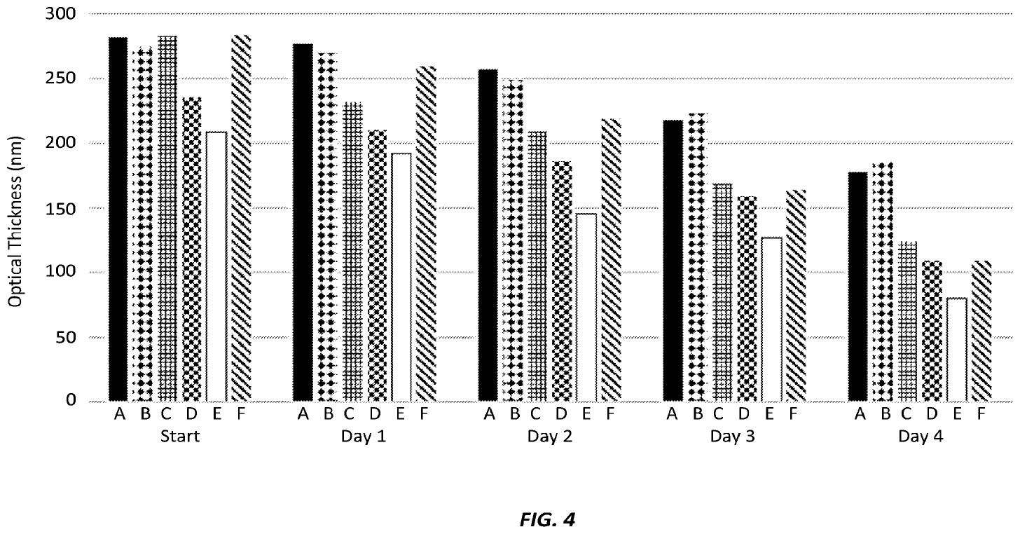

The amount of current generated by a solar cell depends in part upon the likelihood a photon with energy equal to or above the band gap is absorbed within available thickness in a light absorbing material of the perovskite absorber layer. The distance light penetrates before it is absorbed is directly proportional to its wavelength. Blue light is a short wavelength, high energy light absorbed a short distance from the surface of a material. Comparatively, red light is longer wavelength, lower energy light absorbed less strongly and travels further into the material before being absorbed. The current generation will further depend on the optical and electrical properties of the specific materials employed (e.g., light absorption coefficients, photo-generation of free carriers, carrier diffusion lengths for efficient charge transport, non-radiative combination rates, and band gap). The light absorption of a perovskite absorber layer can be characterized in terms of measured Optical Thickness (OT). A commercially available UV-VIS spectrophotometer impinges light of known intensity and selectable wavelength range on a thin film and quantifies the reflected and transmitted light intensities. In accordance with Beer-Lambert Law, a material with higher OT attenuates (absorbs) light more and transmits less than a material with lower OT. If a perovskite absorber layer degrades when exposed to environmental stress conditions, its ability to absorb light will degrade and its relative OT will drop. FIG. 4 shows OT measurements for 6 PALs (Samples A, B, C, D, E and F) exposed to environmental stress conditions over a period of 4 days and exhibiting dropping OT with time, which in a device is expected to result in a dropping PCE. The range of wavelength of visible light measured for OT was 600 nanometers to 800 nanometers, since the lower wavelengths are more strongly absorbed near the surface of the test samples. In all cases the relative OT decreases are consistent with degrading light absorption in the perovskite layer.

The average distance a photon of incident light travels in a light-absorbing material, defined as the Optical Path Length (OPL), can be enhanced beyond the material thickness when light undergoes multiple internal reflections within the device, a phenomenon referred to as “light trapping.” Light trapping techniques that can increase the ratio of OPL to absorber material physical thickness include use of antireflection coatings, textured layers or surfaces (e.g., nanostructured layers or surfaces), and careful material selection to ensure the relative indices of refraction at interfaces promote internal reflections according to Snell's Law. Based on their optical and electrical properties, light trapping is essential for Si-based PVs to achieve high PCE. Unlike Si-based PVs, high performing PSCs reported in literature achieve optimum PCE because of the intrinsic photovoltaic properties of perovskites that lead to highly efficient power conversion without any consideration into maximizing OPL through the utilization of light trapping techniques. That is, since the light absorbance and PCE can be made high for perovskite photovoltaic devices without using light trapping, one would not be motivated to add light trapping features to high-performing perovskite systems since they can add cost and complexity without providing a commensurate benefit to initial PCE. However, it has been unexpectedly found that increasing the ratio of OPL to the physical thickness of the PAL (e.g., by increasing light trapping), while having relatively low effect on initial PCE, can result in significant lifetime improvements for perovskite photovoltaic devices. In some cases, the increase in OPL is measured or calculated within an incident energy range of about the PALs bandgap energy (BE) up to about (BE+0.52 eV). For example, for a perovskite material having a bandgap of about 800 nm, this range may correspond to about 600 nm to 800 nm. The increase in OPL may extend beyond the range of BE to (BE+0.52 eV), but this range has been found to be a representative useful window. The OPL may be an average of OPLs measured at various energies/wavelengths in this range.

A solar cell device physics simulation has been developed to model the impact of Optical Path Length (OPL) to perovskite absorbing layer (PAL) thickness ratio on the long-term power conversion efficiency (PCE) for a PAL with degrading light absorption characterized in terms of Optical Thickness (OT).

### Example 1: Determining the OT Degradation Time Constant of a PAL for Use in a Solar Cell Device Physics Simulation

A PSC was prepared in the solution deposition, roll-to-roll process of the preferred embodiment described above. The structure of the device included a 125 micron flexible, transparent support with several, much thinner, functional layers. On top of the flexible support was a first conducting layer ITO, a first carrier transport layer PTAA, a completed MAPbI₃ perovskite layer with thickness approximately 300 nanometers determined gravimetrically, a second carrier transport layer of C60, and a second conducting layer of copper metal. Jsc and OT data of the PAL test sample collected at STC at regular intervals during an accelerated life test at 85° C. show rapid decrease over time. The Jsc data were superiorly fit to Jsc predicted values for a model PAL with thickness of 311 nanometers, OPL of 4 times the PAL thickness, and accepted absorption coefficients reported in literature. The Jsc and OT for the model PAL were projected to 3000 hours. The OT degradation time constant for the model PAL was extracted from an exponential fit of the projected OT data for use in the solar cell device physics simulation.

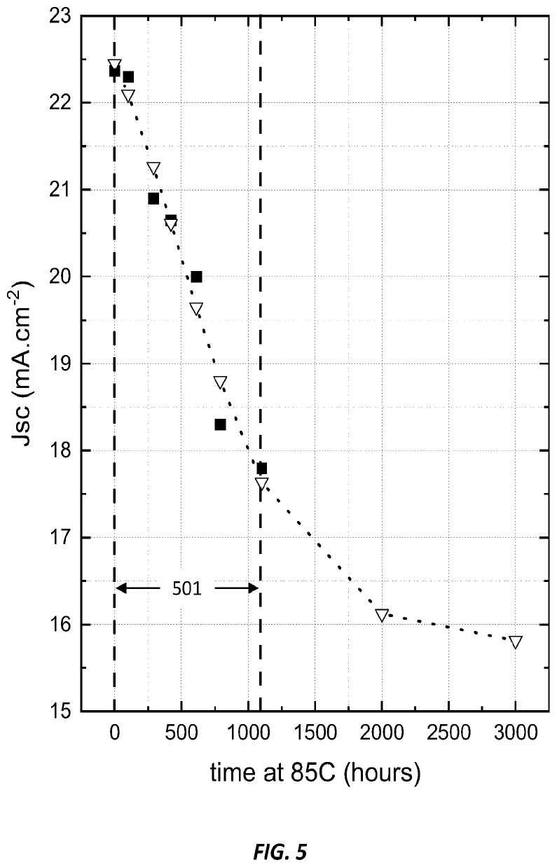

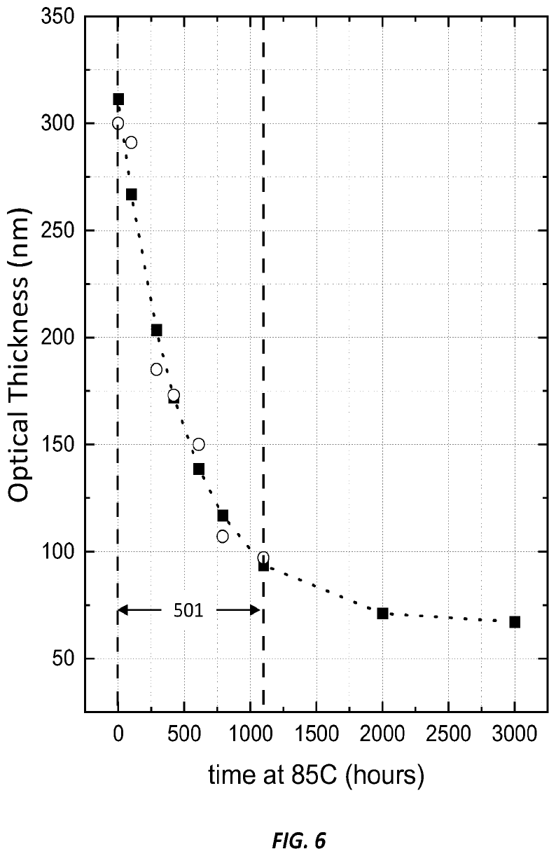

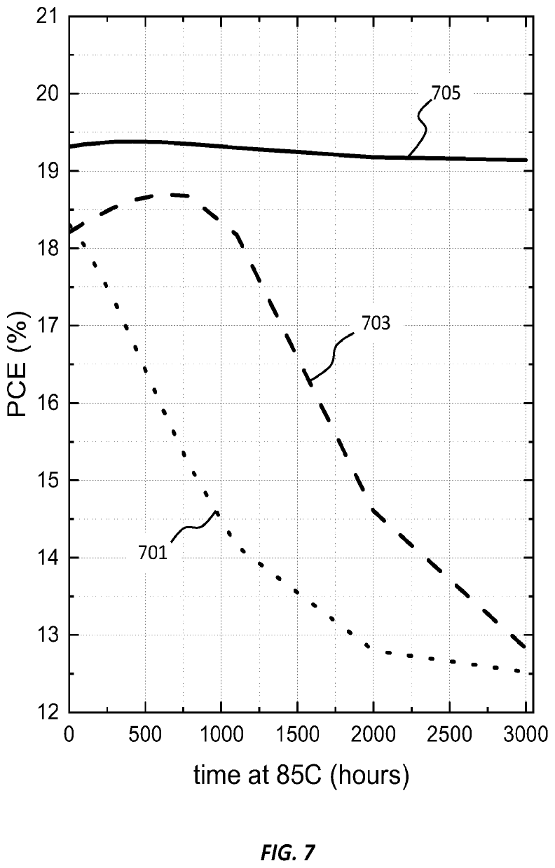

In FIG. 5, the measured Jsc of the test sample (squares) and the projected Jsc (triangles) to 3000 hours for the model PAL (thickness of 311 nanometers; ratio of OPL to PAL thickness of 4) are shown. The vertical dash lines define the measurement period 501 of the test sample. In FIG. 6, the measured OT (circles) and the projected OT (squares) to 3000 hours for the model PAL are shown. In FIG. 7, the perovskite photoconversion efficiency from the solar cell device physics simulation for the model PAL is indicated by the “short-dash” line 701. The PCE drops by almost 30% as the PAL absorbing ability degrades. Other lines are described in Example 2 and Example 3.

### Example 2: Impact of PAL Thickness on PCE Stability

Using the OT degradation time constant extracted for the model PAL with thickness of 311 nanometers and ratio of OPL to PAL thickness of 4 (see Example 1), the PCE of a PAL with initial thickness 2067 nanometers and ratio of OPL to PAL thickness of 4 was simulated. This is almost 7 times higher than 311 nm. As shown in FIG. 7 indicated by the “long-dash” line 703, this significant increase in initial thickness of the PAL to 2067 nanometers with no change in number of internal reflections (OPL) does not substantially mitigate the drop in PCE. Initially, as the PAL degraded, the PCE reached a maximum. However, after the peak, the PCE declined by 30%, and by 3000 hours the PCE not much better than 311 nm PAL. That is, while there was a delay in the onset of PCE degradation, the benefit is temporary. It should be noted also that such a high thickness of PAL, while not impossible, may create numerous practical and significant manufacturing issues (e.g., cost for PAL material, long drying times, defect control, crystal size variability, formation of cracks, and the like) that may more than offset any temporary benefit to PCE. Note that very thick PAL films, like this 2060 nm example, are not practical to make using a single RtR solution deposition because the wet film of ink would not want to stay as a uniform film, being easily affected by gravity and airflow that cause the liquid to move around before it could be completely dried. Using more than one solution deposition with RtR can achieve a thick PAL but this increases the cost of equipment. Relative slower deposition methods, such as vacuum deposition, also can create thick PAL devices but also have higher equipment costs.

### Example 3: Impact of Increasing the Ratio of OPL to PAL Thickness on PCE Stability

Using the OT degradation time constant extracted for the model PAL with thickness of 311 nanometers and ratio of OPL to PAL thickness of 4 (see Example 1), the PCE of a PAL with the same thickness but a much higher ratio of OPL to PAL thickness equal to 28 was simulated. As shown in FIG. 7 indicated by the “solid” line 705, the efficiency stability of a 311 nanometers thin PAL greatly improves as the ratio of OPL to PAL thickness increases, even though the physical thickness of the PAL is only 311 nm. The increased multiple reflections enable the device PCE to maintain a nearly constant value, dropping no more than 1% over 3000 hours exposure to 85° C. despite degradation of the PAL.

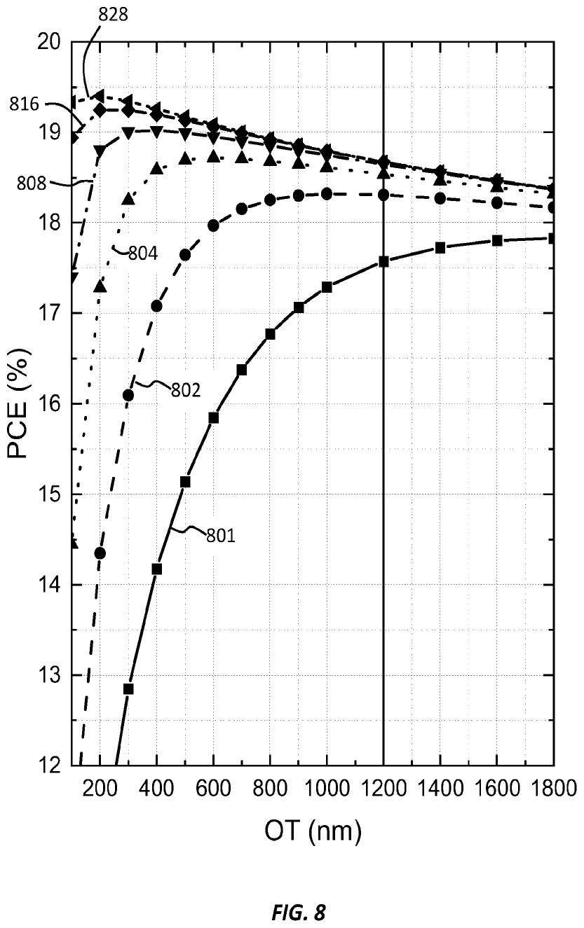

In FIG. 8, photoconversion efficiencies as a function of degrading OT for 5 modeled PALs with starting thickness of 2000 nm over a range of OPL to PAL thickness ratios equal to 1 (line 801), 2 (line 802), 4 (line 804), 8 (line 808), 16 (line 816), and 28 (line 828) were simulated. The initial PCE of the PAL is affected very little by increasing the OPL. The starting PCE for the PAL with OPL to PAL thickness ratio of 28 is only 0.6% higher than the PAL with OPL to PAL thickness ratio of 1. However, the PCE stability improves dramatically with increasing ratio of OPL to PAL thickness. Only with OPL to PAL thickness ratio >4 (e.g., 8 or more) is the drop in PCE kept to an acceptable level of less than 2%. That is, as a PAL degrades over time and its OT drops, the higher OPL-to-PAL thickness ratio helps preserve high PCE. Further, these modeling results demonstrate that high PAL thickness is not necessary to preserve PCE lifetime, and that selection of OPL and PAL thickness may be traded off depending on the needs of the photovoltaic device. Increasing OPL may allow a thinner PAL to be used which may have some manufacturing advantages (material cost, drying time, process control, robust to the formation of cracks, or the like). In some cases, the PAL may have an initial physical thickness up to 2000 nm, but alternatively may be 1000 nm or less, 900 nm or less, 800 nm or less, 500 nm or less, 400 nm or less, 300 nm or less, or even 200 nm or less. In some cases, e.g., for applications that require a semi-transparent PV device (such as architectural windows), the initial PAL thickness may require thinner layers but generally would be at least 50 nm.

Various structural layouts of thin PSCs with improved ratio of OPL to PAL thickness to achieve stable PCE over life can be implemented for mono-facial and bi-facial single junction perovskite solar cell and mono-facial and bi-facial tandem junction perovskite solar cell where the PAL has an OPL greater than or equal to 6 times the PAL thickness, preferably greater than or equal to 8 times the PAL thickness. In some embodiments, an optical path length greater than or equal to 15 times PAL thickness is more preferred. With this novel method of predicting product life, the PAL thickness and the device elements that affect OPL can be optimized for the specific product requirements, including the expected product life, and to minimize manufacturing cost and maximize manufacturing yield.

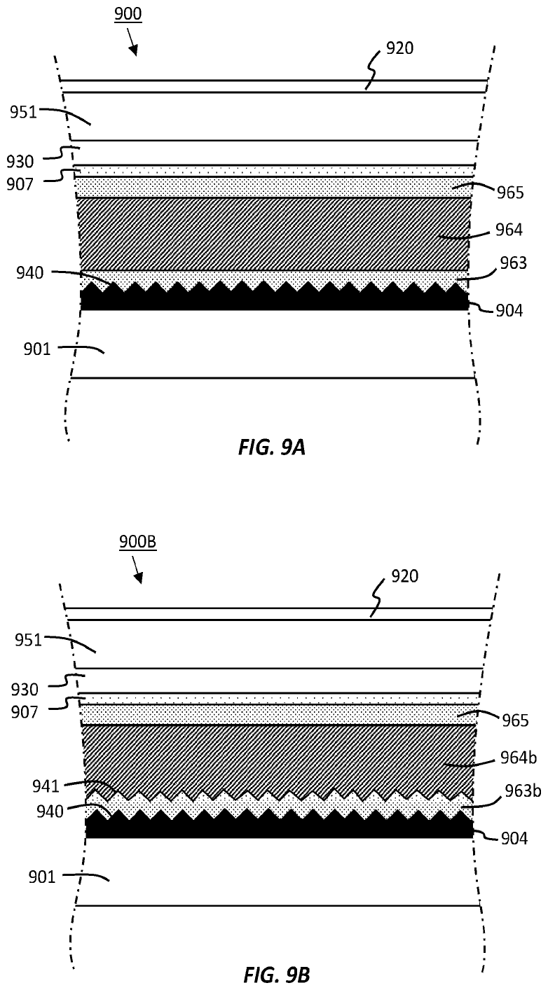

Shown in FIG. 9A is a cross section of a portion of a mono-facial single junction multi-layer perovskite photovoltaic device 900. The structure of the thin film photovoltaic device 900 includes a transparent superstrate 951 having an index of refraction n₂, a transparent adhesive layer 930 having an index of refraction n₃, a transparent conducting layer 907 having an index of refraction n₄, an upper carrier transport layer 965 adjacent to transparent conducting layer and having an index refraction n₅, a perovskite absorber layer 964 having an index of refraction n₆ and an thickness of 900 nm or less (alternatively 500 nm or less or 300 nm or less), a lower carrier transport layer 963 adjacent to the perovskite absorber layer and having an index of refraction n₇, a bottom electrode 904, and a substrate 901. For some applications the thin film perovskite device 900 further includes an anti-reflective coating 920 adjacent to the superstrate and having an index of refraction n₁. In some cases, the bottom electrode 904 is reflective and may optionally include a textured surface 940, e.g., a nanostructured surface. Such textured/nanostructured surface may include features of dimensions capable of interacting with incident light to cause some scattering or production of surface plasmons that may enhance internal reflection. For example, the texture dimensions may be less than 1.5 μm (height, spacing, or the like). In some cases the texture dimensions may be within about 50% of at least some of the target wavelength radiation. The bottom surface of the lower carrier transport layer may also be considered to have a textured surface. For some applications, the transparent superstrate may have a textured surface (not illustrated), e.g., a nanostructured surface having features less than 1.5 microns (height, spacing, or the like). In some cases, the texture dimensions may be within about 50% of at least some of the target wavelength radiation. Whether at the bottom electrode, the superstrate, or for just about any layer or layer interface, textured layers or surfaces, e.g., nanostructured layers or surfaces, can in some cases be used to enhance internal reflections and increase OPL.

There is a wide range of refractive indexes available for each layer depending upon the material chosen. However, in many embodiments ni may be in a range of 1.38-1.5, n₂ may be in a range of 1.5-1.6, n₃ may be in a range of 1.5-1.6, n₄ may be in a range of 1.9 -2.2, n₅ may be in a range of 1.9-2.3, n₆ may be in a range of 2.4-2.7, and n₇ may be in a range of 1.9-2.3. In some embodiments, at least the refractive index of the upper carrier transport layer is lower than the refractive index of the perovskite layer. In some embodiments, the perovskite absorber layer has a refractive index that is higher than refractive indexes of the upper and lower carrier transport layers, i.e., n₅<n₆>n₇. In some cases, the top electrode may have a refractive index that is equal to or less than the refractive index of the upper carrier transport layer, i.e., n₄≤n₅. In some preferred embodiments, the index of refraction values of each layer generally increase from the outer layers towards the perovskite absorber layer, i.e., n₁<n₂≤n₃≤n₄<n₅<n₆>n₇, so as to increase internal reflections of light back to the perovskite absorber layer. In some embodiments, the series may instead be n₁<n₂<n₃<n₄<n₅<n₆>n₇.

FIG. 9B shows another photovoltaic device 900B which is similar to photovoltaic device 900. In device 900, the lower carrier transport layer 963 is coated in a manner so that it is planarizing, i.e., there is no substantial texture at its interface with perovskite absorber layer 964. For device 900B, however, the lower carrier transport layer 963b is provided conformally over the textured bottom electrode. This texture then translates to the interface with perovskite absorber layer 964b, to form a textured surface 941 at this interface, which can also promote internal reflection and increase OPL.

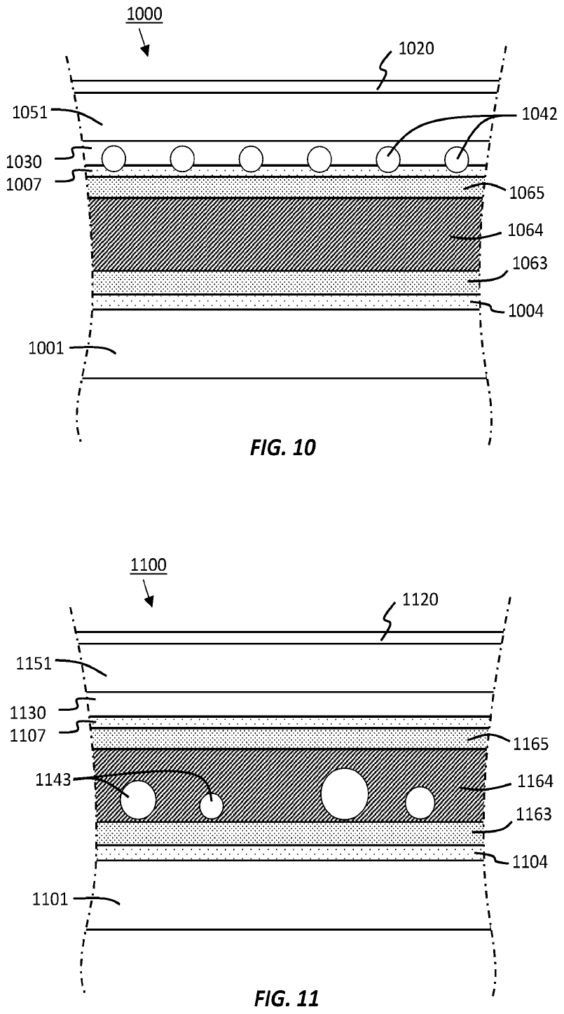

Shown in FIG. 10 is a cross section of a portion of a bi-facial single junction multi-layer perovskite photovoltaic device 1000. The structure of the perovskite photovoltaic device 1000 includes a transparent superstrate 1051 having an index of refraction n₂, a transparent adhesive layer 1030 having an index of refraction n₃, a transparent top electrode 1007 having an index of refraction n₄, an upper carrier transport layer 1065 adjacent to the transparent top electrode and has an index refraction n₅, a perovskite absorber layer 1064 having an index of refraction n₆ and a thickness of 900 nm or less (alternatively 500 nm or less or 300 nm or less), a lower carrier transport layer 1063 adjacent to the perovskite absorber layer having an index of refraction n₇, a transparent bottom electrode 1004 having an index of refraction n₈, and a transparent substrate 1001 with index of refraction n₉. For some applications the thin film perovskite photovoltaic device 1000 further includes an anti-reflective coating 1020 adjacent to the superstrate and having an index of refraction n₁. For some applications, the transparent superstrate has a textured surface (not shown) less than 1.5 microns as discussed with respect to device 900. The refractive indexes of the various layers may also be as described with respect to device 900 with an additional note that, in some cases, n₉<n₈≤n₇, or alternatively n₉<n₈<n₇, so as to increase internal reflections of light back to the perovskite absorber layer.

Photovoltaic device 1000 may further include nanostructure features 1042, e.g., in the form of beads, nanoparticles, nanorods, or the like disposed between adhesion layer 1030 and transparent top electrode 1065. The nanostructure features may form a textured layer or surface to enhance internal reflections and increase OPL. The nanostructure features 1042 may in some cases be partially embedded in the adhesion layer and/or even the top electrode. The nanostructure features 1042 may include materials having a different refractive index relative to one or both of the adhesion layer and the top electrode. In some non-limiting examples, the nanostructures may include metal oxide particles or features, comprising, for example, silicon dioxide, zinc oxide, or titanium dioxide; polymer particles or features comprising, for example, polyester, poly(methyl methacrylate) (PMMA), polyethylene, or the like. The nanostructures may even be porous to further modify their refractive index or other optical property to enhance internal reflections. Although shown as round or spherical, the nanostructure features may instead have just about any other shape, e.g., angular, ellipsoidal, symmetrical, random, or the like. Although shown as having a uniform sizes and spacing, they may instead have a less uniform size distribution and/or may be randomly distributed. The nanostructures may generally be characterized as having at least one dimension that is less than 1500 nm, alternatively less than 1000 nm. In some cases, such dimension may be within about 50% of at least some of the target wavelength radiation. In some embodiments (not shown) the nanostructure features may be provided at some other layer interface.

FIG. 11 is a cross sectional view of another non-limiting example of a bifacial perovskite photovoltaic device according to some embodiments. Perovskite photovoltaic device 1100 includes a transparent superstrate 1151 having an index of refraction n₂, a transparent adhesive layer 1130 having an index of refraction n₃, a transparent top electrode 1107 having an index of refraction n₄, an upper carrier transport layer 1165 adjacent to the transparent top electrode and has an index refraction n₅, a perovskite absorber layer 1164 having an index of refraction n₆ and a thickness of 900 nm or less (alternatively 500 nm or less or 300 nm or less), a lower carrier transport layer 1163 adjacent to the perovskite absorber layer having an index of refraction n₇, a transparent bottom electrode 1104 having an index of refraction n₈, and a transparent substrate 1101 with index of refraction n₉. For some applications the thin film perovskite photovoltaic device 1100 further includes an anti-reflective coating 1120 adjacent to the superstrate and having an index of refraction n₁. The refractive indexes of the various layers may be as described with respect to device 1000.

Photovoltaic device 1100 may further include nanostructure features 1143, e.g., in the form of beads, nanoparticles, nanorods, or the like, embedded in the perovskite absorber layer 1164. The nanostructure features may enhance internal reflections in the perovskite absorber layer and increase OPL. Some or all of the nanostructure features 1143 may be completely embedded in the perovskite absorber layer, or alternatively, some of the nanostructure features may be partially embedded in both the perovskite absorber layer and one or both carrier transport layers. The nanostructure features may, for example, be mixed into a perovskite coating mixture and applied when the perovskite absorber layer material is applied. The nanostructure features 1143 may include materials having a different refractive index relative to the perovskite absorber layer and one or both carrier transport layers. In some non-limiting examples, the nanostructures may include metal oxide particles or features, comprising, for example, silicon dioxide, zinc oxide, or titanium dioxide; polymer particles or features comprising, for example, polyester, poly(methyl methacrylate) (PMMA), polyethylene, or the like. The nanostructures may even be porous to further modify their refractive index or other optical property to enhance internal reflections. Although shown as round or spherical, the nanostructure features may instead have just about any other shape, e.g., angular, ellipsoidal, symmetrical, random, or the like. Although shown as having different sizes and randomly placed, they may instead have a more uniform size distribution and/or may be more uniformly distributed. The nanostructures may generally be characterized as having at least one dimension that is less than 1500 nm, alternatively less than 1000 nm. In some cases, such dimension may be within about 50% of at least some of the target wavelength radiation. In some embodiments (not shown) the nanostructure features may be provided at some other layer interface.

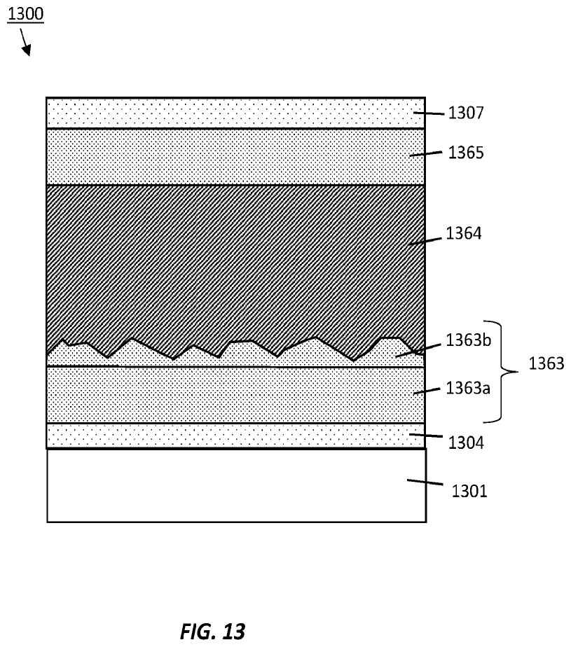

In some embodiments, one or both carrier transport layers include a bilayer structure where one sublayer may be a textured layer (continuous or discontinuous) or have a textured surface and the other sublayer is continuous and less textured or not textured. FIG. 13 is a cross sectional view of another non-limiting example of a perovskite photovoltaic device according to some embodiments. Photovoltaic device 1300 may be mono-facial or bifacial. Although not shown, it may include a superstrate and optical adhesive. Photovoltaic device includes substrate 1301, a bottom electrode 1304 disposed over the substrate, a lower carrier transport layer 1363 disposed over the bottom electrode, a perovskite absorber layer 1364 disposed over the lower carrier transport layer, an upper carrier transport layer 1365 disposed over the perovskite absorber layer, and a top electrode 1307 disposed over the upper carrier transport layer. Lower carrier transport layer 1363 has a multilayer structure including a first sublayer 1363a proximate the bottom electrode that has low or no texturing and a second sublayer 1363b that is a textured layer having a textured surface proximate the perovskite absorber layer. The structure further results in textured interface between the lower carrier transport layer and the perovskite absorber layer. As illustrated, the second sublayer 1363b may be substantially continuous. In some other embodiments, the second sublayer 1363b may instead be discontinuous. The bilayer structure allows even a discontinuous textured carrier transport layer or surface to still function properly. Although not shown, a similar multilayer structure may be provided on the upper carrier transport layer. The materials of the two carrier transport sublayers may be substantially the same or they may be different with respect to chemical composition and/or refractive index. In some preferred embodiments, the textured sublayer may be provided proximate the perovskite absorber layer and the less-or non-textured sublayer may be provided on the side away from the perovskite absorber layer. In some cases, the refractive index of the sublayer adjacent the perovskite absorber layer may be lower than the perovskite material, but higher than the other sublayer positioned away from the perovskite. The other layers of photovoltaic device 1300 may generally have refractive index properties as described elsewhere in order to enhance internal reflections. Photovoltaic device 1300 may further include one or more additional textured layers, textured surfaces, or nanostructure features as described elsewhere in order to enhance internal reflections.

Textured surfaces, nanostructures, refractive index selection, or a combination may be used to produce a perovskite photovoltaic device such that the perovskite absorber layer has an optical path length greater than or equal to 8 times the thickness of the perovskite absorber layer, preferably greater than 15 times the thickness. Each uniquely specified index of refraction may be the averaged measured index of refraction for energies in range of BE to (BE+0.52eV), e.g., for wavelengths in the range of 600 nanometers to 800 nanometers. The thin film perovskite photovoltaic devices of the present disclosure (including but not limited to 900, 900B, 1000, 1100, and/or 1300) may have an open circuit voltage greater than 1.14V for a single junction solar cell at STC of irradiance of 1000 W/m², AM (air mass) 1.5 spectrum, and cell temperature of 25° C. The thin film perovskite photovoltaic devices of the present disclosure (including but not limited to 900, 900B, 1000, 1100, and/or 1300) may have a preferred short circuit current equal to or greater than 90% of the ideal short circuit current as determined from the detailed balance limit at STC of irradiance of 1000 W/m², AM (air mass) 1.5 spectrum, and cell temperature of 25° C.

A mono-facial or bi-facial perovskite photovoltaic device may in some cases have a tandem structure. As is well known, a tandem structure may be a 4-contact type where essentially first and second independent cells are stacked on top of each other, each with its own anode and cathode layer (which may include two substrates). Alternatively, a tandem structure may be a 2-contact type, where there is a single anode and single cathode that sandwiches first and second cells, and there is an intermediate structure (e.g., a recombination layer structure) disposed between the two cells. A tandem cell with two different band gap energies can allow for a broader absorption of light and increase overall efficiency of the device to incident radiation. The perovskite photovoltaic device of the present disclosure may, for example, represent a first cell absorbing a first wavelength range. The second photovoltaic cell may absorb higher or lower wavelengths. In some cases, the second cell's absorber layer is other than a perovskite material. In some preferred embodiments, the second cell includes a second perovskite absorber layer having a bandgap energy BE2 that is less than the bandgap energy BE of the first perovskite absorber layer in the first cell. BE Tandem solar structures are known and can have two active absorber layers (two cells). In some embodiments, BE2 is less than 1.5 eV and BE is 1.5 eV or higher.

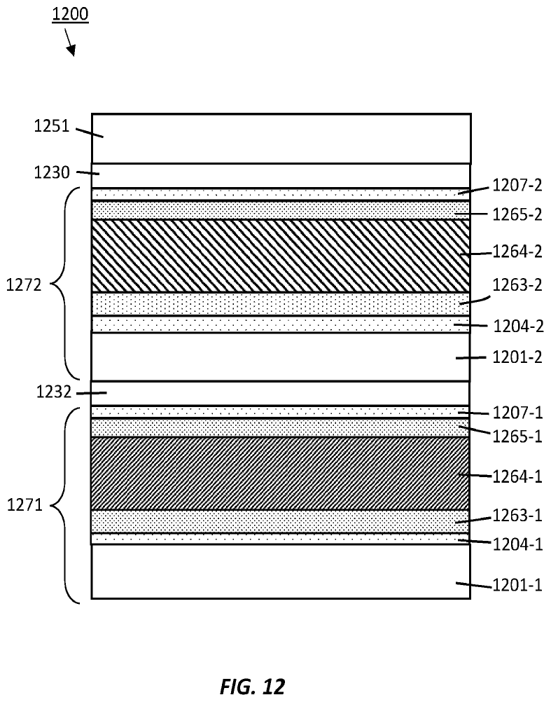

FIG. 12 is a non-limiting example of a tandem perovskite photovoltaic device according to some embodiments. Tandem photovoltaic device 1200 may be characterized as bifacial a 4-contact type and includes a first cell 1271 and a second cell 1272 connected to, and in optical communication with, the first cell by optically transparent adhesive layer 1232. A transparent superstrate 1251 may be attached to an upper portion of the second cell 1272 by an intervening transparent adhesive layer 1230. Each photovoltaic cell may include a substrate 1201-1,2, a bottom electrode 1204-1,2, a lower carrier transport layer 1263-1,2, a perovskite absorber layer 1264-1,2, an upper carrier transport layer 1265-1,2, and a top electrode 1207-1,2. Although not shown, the superstrate may include an antireflection layer as discussed previously.

The tandem photovoltaic device 1200 may in some cases be mono-facial. For example, if light is received through the superstrate, the first cell bottom electrode 1204-1 and/or substrate 1201-1 may be opaque and/or reflective. In such a structure, all other layers except for the perovskite absorber layers are sufficiently transparent to allow each cell to receive its target wavelength range of radiation, which in some preferred embodiments are different for each cell. Alternatively, tandem photovoltaic device 1200 may have a bifacial structure. In such cases, all layers other than the perovskite absorber layers are sufficiently transparent to allow each cell to receive its target wavelength range of radiation, which in some preferred embodiments are different for each cell.

Although not shown, the layers of the tandem device may be selected to have refractive indexes that encourage light trapping and internal reflections as previously described. Further, although not shown, the tandem photovoltaic device may include textured layers or surfaces, nanostructure features, or other elements to encourage light trapping and internal reflections as previously described. In some embodiments, textured layers or surfaces may be tailored so that a first target wavelength range undergoes light trapping in the first cell and a second (different) target wavelength range undergoes light trapping in the second cell.

The disclosed perovskite photovoltaic devices including a relatively thin perovskite absorber layer in combination with a relatively high optical path length to perovskite absorber layer thickness are designed to deliver stable PCE for long product life. Such devices may include a thin perovskite film, built up in layers on an inexpensive flexible substrate using low-cost, scalable high speed R2R deposition and drying processes, having inherently less defects, lower consumption of pre-cursor raw materials, and higher PCE than thicker coatings made in the same process, incorporated into a PSC designed for high optical path length to perovskite absorber thickness.

1. A thin film photovoltaic device configured for receiving and converting a target wavelength range of light to electricity, comprising:
a substrate;
a bottom electrode disposed over the substrate;
a lower carrier transport layer disposed over the bottom electrode;
a perovskite absorber layer disposed over the lower carrier transport layer, wherein the perovskite absorber layer has a physical thickness of 900 nm or less and is characterized by a bandgap energy (BE);
an upper carrier transport layer disposed over the perovskite absorber layer; and
a top electrode disposed over the upper carrier transport layer,
wherein at least one of the top and bottom electrodes comprises a transparent conducting layer which is transparent to the target wavelength range of light,
and wherein the perovskite absorber layer has an optical path length that is greater than or equal to 8 times the physical thickness of the perovskite absorber layer for incident radiation that is i) within the target wavelength range, and ii) within an incident energy range of BE to (BE+0.52 eV).

2. The photovoltaic device of claim 1, wherein the incident radiation is in range of 600 to 800 nm.

3. The photovoltaic device of claim 1 or 2, wherein the perovskite absorber layer has a refractive index that is greater than i) a refractive index of the upper carrier transport layer, ii) a refractive index of the lower carrier transport layer, or iii) both (i) and (ii).

4. The photovoltaic device according to any of claims 1-3, wherein the transparent conducting layer has a refractive index that is less than i) a refractive index of the upper carrier transport layer, ii) a refractive index of the lower carrier transport layer, or iii) both (i) and (ii).

5. The photovoltaic device according to any of claims 1-4, wherein the substrate is transparent, and wherein the bottom electrode is a transparent electrode comprising the transparent conducting layer.

6. The photovoltaic device of claim 5, wherein the top electrode comprises a reflective metal layer.

7. The photovoltaic device of claim 5 or 6, wherein the bottom electrode further comprises a bottom pattern of metal lines in contact with the transparent conducting layer.

8. The photovoltaic device according to any of claims 1-4, wherein the top electrode is a transparent electrode and comprises the transparent conducting layer.

9. The photovoltaic device of claim 8, wherein the top electrode further comprises a top pattern of metal lines in contact with the transparent conducting layer.

10. The photovoltaic device of claim 8 or 9, wherein the bottom electrode comprises a reflective metal layer.

11. The photovoltaic device of claim 8 or 9, further comprising a reflective or opaque light scattering layer provided i) as part of the substrate, or ii) attached to the substrate, wherein the bottom electrode is a transparent bottom electrode.

12. The photovoltaic device according to any of claims 8-9, wherein the substrate is transparent, and wherein the bottom electrode is a transparent electrode comprising a bottom transparent conducting layer.

13. The photovoltaic device of claim 12, wherein the bottom electrode further comprises a bottom set of metal lines in contact with the bottom transparent conducting layer.

14. The photovoltaic device according to any of claims 8-13, further comprising a transparent superstrate and a transparent adhesive layer interposed between the transparent superstrate and the transparent top electrode.

15. The photovoltaic device of claim 14, further comprising an antireflection layer disposed over the transparent superstrate.

16. The photovoltaic device according to any of claims 1-15, further comprising at least one textured layer or textured surface selected for increasing the optical path length.

17. The photovoltaic device of claim 16, wherein the textured layer or textured surface comprises a nanostructured layer or a nanostructured surface.

18. The photovoltaic device of claim 16 or 17, wherein textured layer or textured surface has a surface roughness of greater than 0.5 μm.

19. The photovoltaic device according to any of claims 16-18, wherein the textured surface corresponds to a surface of the substrate, the bottom electrode, the lower carrier transport layer, the perovskite absorber layer, the upper carrier transport layer, or the top electrode.

20. The photovoltaic device according to any of claims 16-18, wherein the textured surface corresponds to a surface of another device layer positioned over the top electrode or under the substrate.

21. The photovoltaic device according to any of claims 16-20, wherein the textured layer or textured surface comprises nanoparticles.

22. The photovoltaic device of claim 21, wherein the nanoparticles are at least partially embedded in a layer comprising a material having a different chemical composition and index of refraction relative to the nanoparticles.

23. The photovoltaic device of claim 21 or 22, wherein the nanoparticles are provided at an interface of two device layers, each having a different chemical composition and index of refraction relative to the nanoparticles.

24. The photovoltaic device according to any of claims 21-23, wherein the perovskite absorber layer comprises an active perovskite material and the nanoparticles are at least partially embedded within the active perovskite material, the nanoparticles having a lower refractive index than a refractive index of the active perovskite material.

25. The photovoltaic device according to any of claims 21-24, wherein the transparent layer comprises or is in contact with the nanoparticles.

26. The photovoltaic device according to any of claims 16-25, comprising two or more textured layers or textured surfaces.

27. The photovoltaic device according to any of claims 16-26, wherein at least one carrier transport layer comprises a multilayer structure comprising a first sublayer and a second sublayer, wherein one of the sublayers comprises the textured layer or textured surface, and the other sublayer does not comprise a textured layer or textured surface.

28. The photovoltaic device according to any of claims 1-27, wherein the optical path length is greater than or equal to 15 times the physical thickness of the perovskite absorber layer.

29. The photovoltaic device according to any of claims 1-28, wherein the perovskite absorber layer has a physical thickness of 500 nm or less.

30. The photovoltaic device according to any of claims 1-28, wherein the perovskite absorber layer has a physical thickness of 300 nm or less.

31. The photovoltaic device according to any of claims 1-30, characterized by an open circuit voltage greater than 1.14 V for a single junction solar cell under an irradiance of 1000 W/m², air mass 1.5 spectrum, and at cell temperature of 25° C.

32. The photovoltaic device according to any of claims 1-31, characterized by an open circuit voltage that is within a range of 92%-100% of an ideal open circuit voltage for a single junction solar cell under an irradiance of 1000 W/m², air mass 1.5 spectrum, and at cell temperature of 25° C. .

33. The photovoltaic device according to any of claims 1-32, characterized by an short circuit current that is equal or greater than 90% of an ideal short circuit current as determined from a detailed balance limit for a single junction solar cell under an irradiance of 1000 W/m², air mass 1.5 spectrum, and at cell temperature of 25° C. .

34. The photovoltaic device according to any of claims 1-33, wherein the target wavelength range is within a range of at least 450 nm to 800 nm.

35. The photovoltaic device according to any of claims 1-34, further comprising a tandem structure, the tandem structure comprising:
a) a first cell including the bottom electrode, the lower carrier transport layer, the perovskite absorber layer, the upper carrier transport layer, and the top electrode; and
b) a second cell in optical communication with the first cell, the second cell comprising a second perovskite absorber layer having a second bandgap energy (BE2), wherein BE2 is less than BE.
